(19) United States
(12) Patent Application Publication
(10) Pub. No.: US 2025/0232959 A1
(43) Pub. Date: Jul. 17, 2025

(54) DEPOSITION TOOL WITH DIELECTRIC COATED CHAMBER SIDEWALLS TO IMPROVE ELECTROMANGNETIC FIELD UNIFORMITY

(71) Applicant: Taiwan Semiconductor Manufacturing Company, Ltd., Hsinchu (TW)

(72) Inventors: Yen-Liang LIN, Yilan County (TW); Ru-Liang LEE, Hsinchu City (TW); Chung-Yi YU, Hsin-Chu (TW); Yao-Wen CHANG, Taipei (TW); Kuo Liang KU, Hsinchu City (TW); Bo-Han CHU, Taipei City (TW); Min-Chang CHING, Tainan (TW)

(21) Appl. No.: 18/412,071

(22) Filed: Jan. 12, 2024

(51) Int. Cl. H01J 37/32; C23C 14/34; C23C 14/50; H10N 30/093

(52) U.S. Cl. CPC H01J 37/32477; C23C 14/34; C23C 14/50; H01J 37/32715; H10N 30/093

(57) ABSTRACT

Some implementations described herein provide a deposition tool and methods of operation. The deposition tool may be used in the fabrication of integrated circuit devices to deposit materials and/or layers on a semiconductor substrate. The deposition tool may include a chamber (e.g., a processing chamber) that is coated with a dielectric coating on sidewalls of the chamber. The dielectric coating on the sidewalls of the chamber within the deposition tool increases a likelihood of a negative charge accumulating near the sidewalls of the chamber. The increased likelihood of negative charge accumulation near the sidewalls of the chamber may improve a uniformity of an electromagnetic field within the deposition tool (e.g., during a deposition operation) relative to another deposition too not including such a dielectric coating. The improved uniformity of the electromagnetic field may enable an improved uniformity of a material being deposited by the deposition tool to be achieved.

### BACKGROUND

A physical vapor deposition (PVD) tool, such as a sputtering tool (or sputter deposition tool) includes a semiconductor processing tool that performs a physical vapor deposition operation within a processing chamber to deposit material onto a semiconductor substrate such as a wafer. The material may include a metal, a dielectric, or another type of material. A physical vapor deposition operation (such as a sputtering operation) may include placing the semiconductor substrate on an anode in a processing chamber, in which a gas is supplied and ignited to form a plasma of ions of the gas. The ions in the plasma are accelerated toward a cathode formed of the material to be deposited, which causes the ions to bombard the cathode and release particles of the material. The anode attracts the particles, which causes the particles to travel toward and deposit onto the semiconductor substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor processing system described herein.

FIG. 2 is an example deposition tool described herein.

FIGS. 3A and 3B are diagrams related to an example chamber of a deposition tool described herein.

FIG. 4A-4C are diagrams of example implementations described herein.

FIG. 5A-5C are diagrams of an example deposition operation described herein.

FIGS. 6-8 are diagrams of example data related to deposition of a material using a deposition tool described herein.

FIG. 9 is a diagram of example components of a device associated with a deposition tool described herein.

FIG. 10 is a flowchart of an example process associated with the deposition tool of FIG. 2.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a distribution of an electromagnetic field within a chamber of a PVD tool may correspond to a distribution of a plasma (e.g., a distribution of an acceleration of ions) within the chamber. Furthermore, a uniformity of a material being deposited by the PVD tool may correlate substantially with the distribution of the electromagnetic field. A variation in the uniformity (e.g., a thickness) of the material being deposited may, in some cases, result in variation in a dimension or a physical property related to an integrated circuit device being formed on the semiconductor substrate, which in turn can degrade a performance of the integrated circuit device and/or result in reduced integrated circuit device yield.

For example, a microphone included as part of an integrated circuit device may include a plurality of piezoelectric structures. The microphone may be formed using semiconductor processing techniques, which may include the use of the PVD tool to deposit an aluminum material over the piezoelectric structures to electrically connect the plurality of piezoelectric structures with other circuitry or features of the integrated circuit device. In a case where the PVD tool does not deposit the aluminum material uniformly across the semiconductor substrate, a range between a maximum height and a minimum height of structures including the plurality of piezoelectric structures (and the aluminum material) may exceed a threshold and become “mismatched,” which may reduce a performance of the microphone of the integrated circuit device.

Some implementations described herein provide a deposition tool and methods of operation. The deposition tool may be used in the fabrication of integrated circuit devices to deposit materials and/or layers on a semiconductor substrate. The deposition tool may include a chamber (e.g., a processing chamber) that is coated with a dielectric coating on sidewalls of the chamber. The dielectric coating on the sidewalls of the chamber within the deposition tool increases a likelihood of a negative charge accumulating near the sidewalls of the chamber. The increased likelihood of negative charge accumulation near the sidewalls of the chamber may improve a uniformity of an electromagnetic field within the deposition tool (e.g., during a deposition operation) relative to another deposition too not including such a dielectric coating. The improved uniformity of the electromagnetic field may enable an improved uniformity of a material being deposited by the deposition tool to be achieved.

In this way, the dielectric coating described herein on the sidewalls of the chamber of the deposition tool may enable an increased integrated circuit device yield to be achieved relative to another to integrated circuit device yield that is achievable by another deposition tool that does not include the dielectric coating. By increasing the yield, an amount of resources needed to support a market of the integrated circuit devices (e.g., raw materials, labor, semiconductor manufacturing tools, and/or computing resources) is reduced. Furthermore, the improved uniformity may enable an increased performance for devices (e.g., microphones and/or other devices) of integrated circuit devices processed by the deposition too.

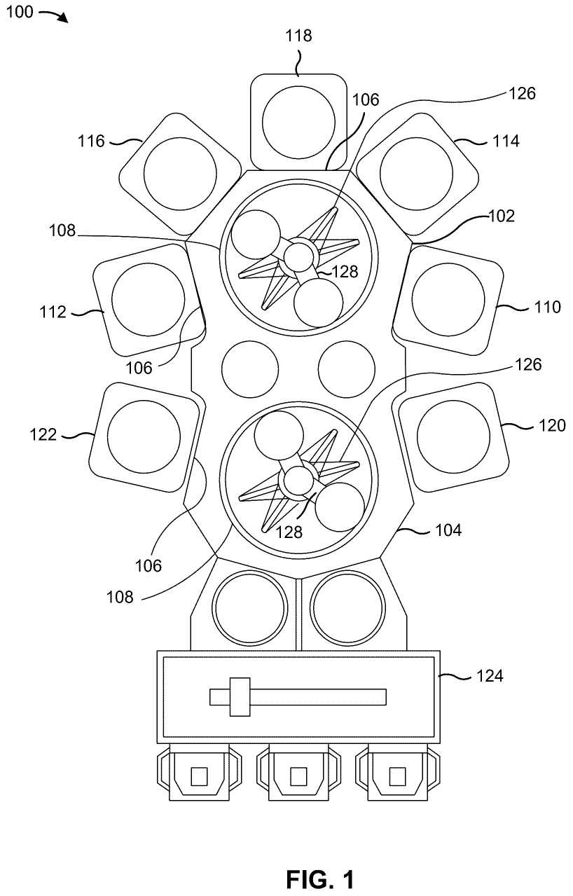

FIG. 1 is a diagram of an example semiconductor processing system 100 described herein. The semiconductor processing system 100 may perform one or more deposition processes, such as a physical vapor deposition (PVD) process, a chemical vapor deposition (CVD) process, a plasma-enhanced CVD (PECVD) process, a high-density plasma CVD (HDP-CVD) process, a sub-atmospheric CVD (SACVD) process, an atomic layer deposition (ALD) process, and/or a plasma-enhanced atomic layer deposition (PEALD) process, among other examples. As described herein, a physical vapor deposition process may correspond to a sputtering process.

In some implementations, and as shown in FIG. 1, the semiconductor processing system 100 includes one or more main frames 102, 104 having a plurality of sidewalls 106. The main frames 102, 104 and the plurality of sidewalls 106 may provide structural support to the semiconductor processing system 100.

A plurality of vacuum load lock chambers 108 is located in the center of main frames 102, 104. In some implementations, one or more of the vacuum load lock chambers 108 is maintained in a vacuum state to stage semiconductor substrates (e.g., silicon wafers, among other examples) for processing within the semiconductor processing system 100 to receive the semiconductor substrates after processing within the semiconductor processing system 100. Each of the plurality of vacuum load lock chambers 108 spatially separates the semiconductor substrates from processing chambers of the semiconductor processing system 100.

The semiconductor processing system 100 includes a plurality of processing chambers 110, 112, 114, 116, 118, 120, and 122. Each processing chamber may include one or more components to deposit material using a deposition process onto a semiconductor substrate received from one of the plurality of vacuum load lock chambers 108.

An external semiconductor substrate elevator 124 is located adjacent to the semiconductor processing system 100. In some implementations, the external semiconductor substrate elevator 124 is a part of the semiconductor processing system 100. In some implementations, the external semiconductor substrate elevator 124 is a component that is separate from the semiconductor processing system 100. The external semiconductor substrate elevator 124 is configured to hold a cassette containing a plurality of semiconductor substrates. The external semiconductor substrate elevator 124 also includes an automatic distributor for selecting a semiconductor substrate from the plurality of semiconductor substrates and timely supplying the selected semiconductor substrate to one of the plurality of vacuum load lock chambers 108 to stage for processing by one of the processing chambers 110-122.

The semiconductor processing system 100 may further include, within one or more of the plurality of vacuum load lock chambers 108, a semiconductor substrate transfer system 126 including a plurality of robotic arms 128. The semiconductor substrate transfer system 126, including the plurality of robotic arms 128, may operate in conjunction with the external semiconductor substrate elevator 124 to transport semiconductor substrates amongst a cassette on the external semiconductor substrate elevator 124, and to and/or from one or more of the processing chambers 110-122.

One or more of the processing chambers 110-122 may be subjected to a deposition operation to clean the one or more of the processing chambers 110-122 and to maintain a degree of cleanliness in the one or more of the processing chambers 110-122. Examples of such a deposition operation include a burn-in deposition operation that forms a plasma to remove particulates from a target structure material within the one or more of the processing chambers 110-122, a pasting deposition operation that coats an interior surface within the one or more of the processing chambers 110-122 to prevent flaking of particulates from the interior surface, and/or another deposition operation.

As indicated above, FIG. 1 is provided as an example. Other examples may differ from what is described with regard to FIG. 1. For example, another example may include additional components, fewer components, different components, or differently arranged components than those shown in FIG. 1. Additionally, or alternatively, a set of components (e.g., one or more components) of FIG. 1 may perform one or more functions described herein as being performed by another set of components.

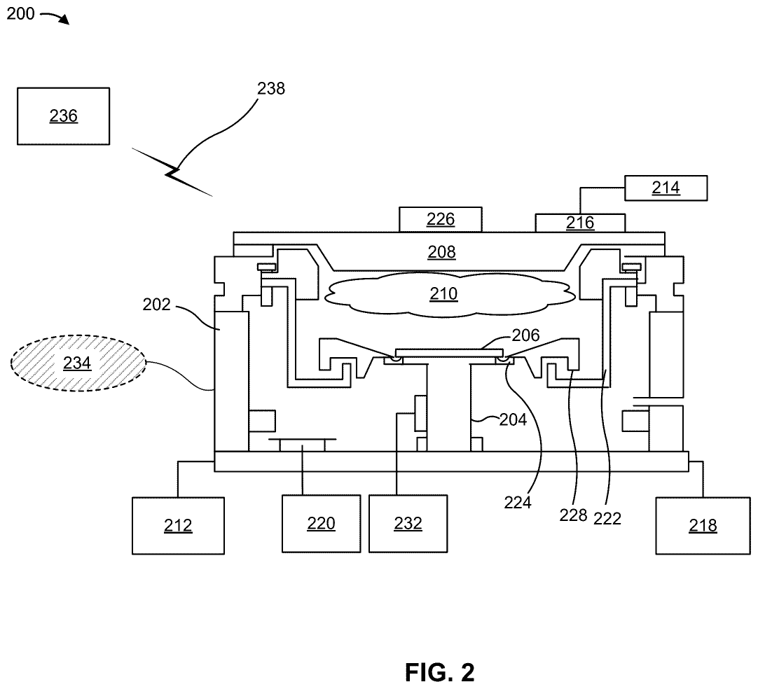

FIG. 2 is an example deposition tool 200 described herein. In some implementations, the deposition tool 200 is for use in the semiconductor processing system 100 of FIG. 1. The deposition tool 200 includes a processing chamber 202 which may correspond to one of the processing chambers 110-122 as described in connection with FIG. 1. The deposition tool 200 further includes a pedestal component 204 including a chuck (e.g., an electrostatic chuck (ESC) or a vacuum chuck, among other examples) upon which a semiconductor substrate 206 (e.g., a semiconductor wafer) is positioned and secured. In some implementations, the pedestal component 204 includes a heating component (e.g., a hot plate, among other examples) to provide heat to the semiconductor substrate 206 during the deposition process and/or the sputtering operation. The pedestal component 204 may be, for example, fabricated from aluminum, stainless steel, ceramic, or combinations thereof.

In some implementations, the deposition tool 200 includes a target structure 208. The target structure 208 may include a material to be deposited on to the semiconductor substrate 206. The target structure 208 may include a tantalum nitride (TaN) material, a lead zirconate titanate material, a silicon nitride (SiN) material, a silicon dioxide (SiO₂) material, a tantalum pentoxide material, or a cobalt iron boron material, among other examples.

Within the processing chamber 202, a plasma 210 may be formed from a gas (e.g., krypton (Kr), argon (Ar), or another chemically inert gas, among other examples) and supplied between the target structure 208 and the semiconductor substrate 206. One or more electrical bias voltages may be applied to the target structure 208 and or the pedestal component 204. An electrical bias may be applied to the target structure 208 to cause ions in the plasma 210 to accelerate towards the target structure 208 to sputter etch the target structure 208. This causes material of the target structure 208 to be dislodged and mobilized. An electrical bias may be applied to the pedestal component 204 to generate an electrical potential or electric field between the target structure 208 and the semiconductor substrate 206. This promotes or facilitates a flow of particulates of the inert metal material that are dislodged from the target structure 208 toward the semiconductor substrate 206. In some implementations, applying the electrical bias to the pedestal component 204 may modulate an electromagnetic field (e.g., alter or change a magnetic flux or strength of the electromagnetic field, among other examples) between the semiconductor substrate 206 and the target structure 208.

An example of a biasing power source that may be included in the deposition tool 200 includes a radio frequency (RF) power circuit 212. The radio frequency power circuit 212 generates a radio frequency bias voltage within the processing chamber 202. The radio frequency bias voltage may promote or facilitate a flow of the inert metal material that was dislodged from the target structure 208 toward the semiconductor substrate 206. Another radio frequency bias voltage may be used in connection with generating the plasma 210 and/or accelerating ions in the plasma 210 toward the target structure 208.

Another example of a biasing power source that may be included in the deposition tool 200 includes a direct current (DC) power circuit 214. The direct current power circuit 214 generates direct current power in the form of a direct current bias voltage. In some implementations, the direct current power circuit 214 is connected to the target structure 208 using an electrode 216 and is configured to supply the target structure 208 with the direct current bias voltage. In some implementations, the direct current bias voltage provided to the target structure 208 by the direct current power circuit 214 is included in a range of approximately 250 volts to approximately 300 volts. However, other values and ranges for the direct current bias voltage provided by the direct current power circuit 214 are within the scope of the present disclosure.

In some implementations, the deposition tool 200 includes a gas supply system 218 that supplies one or more gases used to form plasmas (e.g., the plasma 210 used for the deposition process or another plasma used for the deposition operation, among other examples). The gas supply system 218 may control a rate of flow of the gas (e.g., argon (Ar) or krypton (Kr), among other examples), which controls one or more parameters of the plasma 210 including the ionization rate in the plasma 210, the ion passivation rate on the semiconductor substrate 206, and/or another parameter.

The deposition tool 200 further includes a vacuum pump 220. The vacuum pump 220 is connected to the deposition tool 200. The vacuum pump 220 is configured to create a vacuum state in the processing chamber 202 during the deposition process and/or the deposition operation. During a sputtering operation, the vacuum pump 220 may maintain a pressure within the processing chamber 202 to approximately 5 millitorrs (mtorr) or less. However, other values for the pressure maintained within the processing chamber 202 by the vacuum pump 220 are within the scope of the present disclosure.

The deposition tool 200 further includes a lower shield 222 and a platen ring 224. The lower shield 222 may shield the semiconductor substrate 206 during the deposition process. The platen ring 224 may assist maintaining a position of the semiconductor substrate 206 during the deposition process. The platen ring 224 may be fabricated from a material that can resist erosion by the generated plasma 210, for example, a metallic material such as stainless steel, titanium, or aluminum, or a ceramic material such as aluminum oxide. However, another suitable material may be used such as a synthetic rubber, a thermoset, a plastic, a thermoplastic, or any other material that meets a chemical compatibility, durability, sealing, and/or temperature requirement of the deposition process and/or the deposition operation.

The deposition tool 200 further includes a magnet component 226. In some implementations, the magnet component 226 enhances consumption of the inert metal material from the target structure 208 during the deposition process. In some implementations, the magnet component 226 corresponds to an electromagnet. The magnet component 226 may, in some implementations, include an array or combinations of magnets.

In some implementations, the deposition tool 200 includes an upper shield 228. The upper shield 228 is positioned adjacent to the lower shield 222. The upper shield 228 may be supported by the lower shield 222. The lower shield 222 and the upper shield 228 cooperate to reduce or eliminate materials from the target structure 208 from coming in contact with components (e.g., the pedestal component 204) of the deposition tool 200. The lower shield 222 and the upper shield 228 may be fabricated from a material that can resist erosion by the generated plasma 210, such as a stainless-steel material, a titanium material, an aluminum material, or a ceramic material, among other examples.

As shown in FIG. 2, the deposition tool 200 further includes a pedestal component positioning system 232. The pedestal component positioning system 232 (a servo motor with mechanical linkages, among other examples) may connect with the pedestal component 204. The pedestal component positioning system 232 may adjust a height or a vertical position of the pedestal component 204 to adjust a height or a vertical position of the semiconductor substrate 206 within the processing chamber 202.

The deposition tool 200 includes a dielectric coating 234 on sidewalls of the processing chamber 202. The dielectric coating 234 may include an aluminum oxide material (Al₂O₃), an aluminum nitride material (AlN), a silicon nitride material (SiN), a tantalum nitride material (TaN), a tantalum pentoxide material (Ta₂O₅), or a yttrium oxide material (Y₂O₃), among other examples. In some implementations, the dielectric coating 234 is included on the interior surfaces of the sidewalls within the processing chamber 202. Additionally, or alternatively and in some implementations, the dielectric coating 234 is omitted from the exterior surfaces of the sidewalls of the processing chamber 202. Additionally, or alternatively and in some implementations, the dielectric coating 234 is on bottom surfaces of the processing chamber 202. Additionally, or alternatively and in some implementations, the dielectric coating is on components within the processing chamber 202 (e.g., the lower shield 222, the platen ring 224, and/or the upper shield 228).

A dielectric material of the dielectric coating 234 may include one or more electrical performance properties. For example, the dielectric material of the dielectric coating 234 may include a dielectric strength that is greater than approximately 15 kilovolts per millimeter (kV/mm). Selecting the dielectric material having a dielectric strength of at least approximately 15 kV/mm increases a robustness of the dielectric coating 234 to withstand electromagnetic fields within the processing chamber 202 during repeated deposition operations and extend a useable lifetime of the dielectric coating 234. Conversely, selecting a dielectric material having a dielectric strength of less than approximately 15 kV/mm weakens the dielectric coating 234 and may increase a risk of the dielectric coating 234 breaking down during repeated deposition operations to decrease a useable lifetime of the dielectric coating 234. However, other values and ranges for the dielectric strength are within the scope of the present disclosure.

Additionally, or alternatively, a dielectric material of the dielectric coating 234 may have an impedance that is greater than approximately 300 ohms (Ω). Selecting the dielectric material having an impedance of at least approximately 300Ω increases a likelihood of an accumulation of electrons (e.g., a negative charge) near the sidewalls of the processing chamber 202 to substantially improve a uniformity of an electromagnetic field/plasma distribution within the processing chamber 202 during a deposition operation. Conversely, selecting a dielectric material having an impedance of at least approximately 300Ω reduces a likelihood of an accumulation of electrons (e.g., a negative charge) near the sidewalls of the processing chamber 202, thereby failing to substantially improve a uniformity of an electromagnetic field/plasma distribution within the chamber during a deposition operation. However, other values and ranges for the dielectric strength are within the scope of the present disclosure.

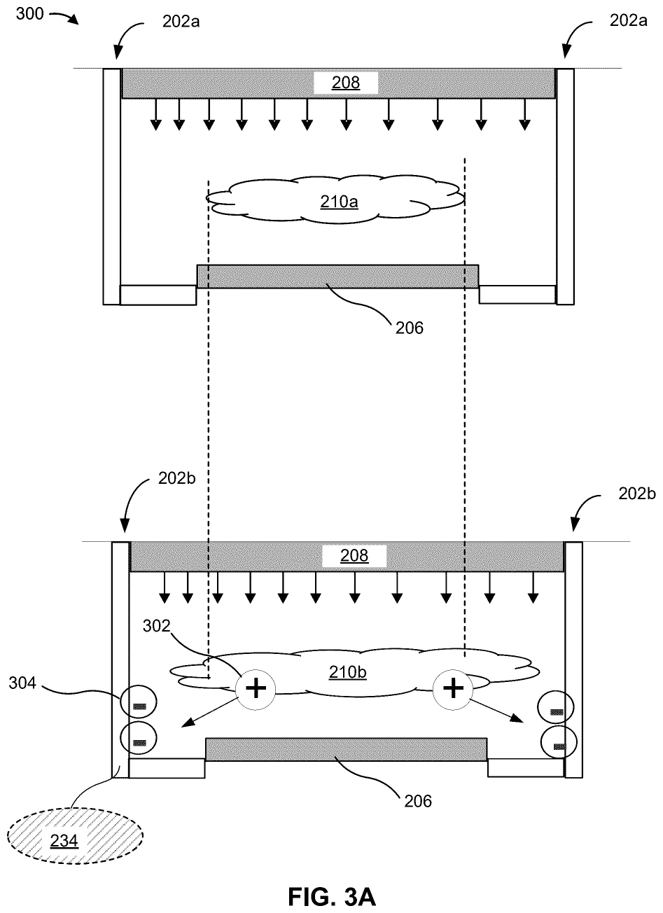

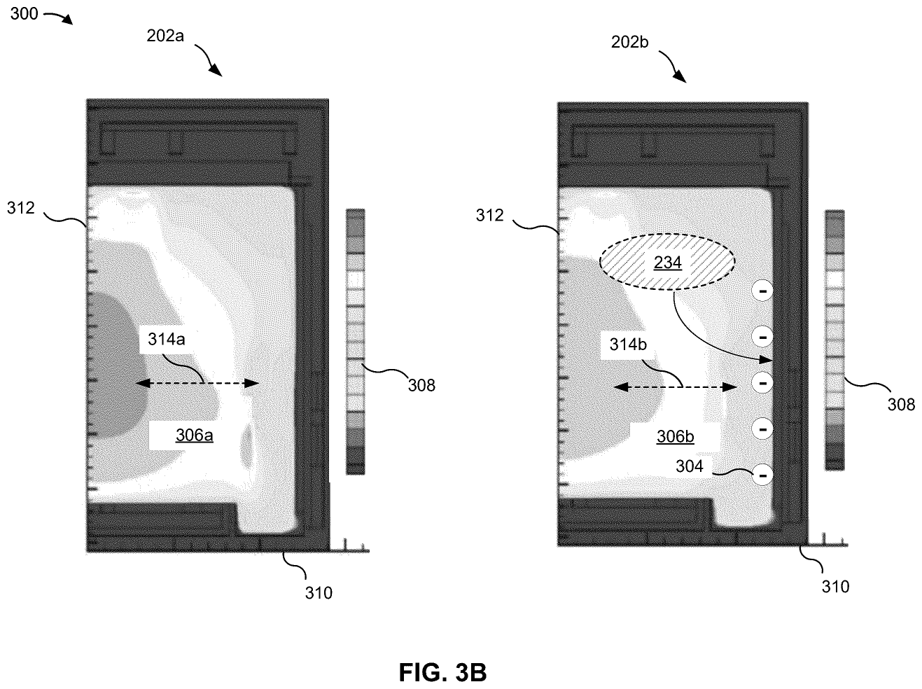

As described in greater detail in connection with FIGS. 3A and 3B, the dielectric coating 234 may cause an accumulation of the negative charge within the processing chamber 202 during a deposition operation (e.g., a sputtering operation). In some implementations, a location of an accumulation of the negative charge may improve a uniformity of an electromagnetic field the processing chamber 202 to reduce a mismatch profile of a layer of a material deposited on a semiconductor substrate 206 during the deposition operation.

In this way, a yield of a population of integrated circuit devices (fabricated using the deposition tool 200) is increased relative to another population of integrated devices fabricated using another deposition tool that does not include the dielectric coating 234 on sidewalls of a chamber. By increasing the yield of the population of integrated circuit devices, an amount of resources needed to support a market of the integrated circuit devices (e.g., raw materials, labor, semiconductor manufacturing tools, and/or computing resources) is reduced.

The deposition tool 200 further includes a controller 236. The controller 236 (e.g., a processor, a combination of a processor and memory, among other examples) may communicatively couple to one or more components of the deposition tool 200 (e.g., the radio frequency power circuit 212, the direct current power circuit 214, the gas supply system 218, and/or the direct current power circuit 214, among other examples) using one or more communication links 238. The one or more communication links 238 may include or more wireless-communication links, one or more wired-communication links, or a combination of one or more wireless-communication links and one or more wired-communication links, among other examples. In some implementations, the controller 236 is configured to monitor an amount of the power provided by the direct current power circuit 214 to the pedestal component 204 (e.g., monitor the one or more sensors in the direct current power circuit 214). In some implementations, the controller 236 is external to the deposition tool 200.

In some implementations, the controller 236 adjusts a setting that controls a vertical position of the pedestal component positioning system 232 to adjust a uniformity of an electromagnetic field within the processing chamber 202 during a plasma-based deposition operation. Furthermore, the controller 236 may adjust the setting based on a machine learning model. The machine learning model may include and/or may be associated with one or more of a neural network model, a random forest model, a clustering model, and/or a regression model, among other examples. In some implementations, the controller 236 uses the machine learning model to estimate a uniformity of a material being deposited on the semiconductor substrate 206 by providing a candidate material included in the dielectric coating 234 as an input to the machine learning model, and using the machine learning model to determine a likelihood, probability, or confidence that a particular outcome (e.g., the uniformity) for a subsequent deposition operation (e.g., a sputtering operation) will be achieved using the candidate material. Additionally, or alternatively, the controller 236 uses the machine learning model to estimate the uniformity of the material being deposited on the semiconductor substrate 206 by providing a candidate sidewall coverage height of the dielectric coating 234 as an input to the machine learning model, and using the machine learning model to determine a likelihood, probability, or confidence that a particular outcome (e.g., the uniformity) for a subsequent deposition operation (e.g., a sputtering operation) will be achieved using the candidate sidewall coverage height. Additionally, or alternatively, the controller 236 uses the machine learning model to estimate the uniformity of the material being deposited on the semiconductor substrate 206 by providing a candidate material to be deposited by a plasma-based deposition operation as an input to the machine learning model, and using the machine learning model to determine a likelihood, probability, or confidence that a particular outcome (e.g., the uniformity) for a subsequent deposition operation (e.g., a sputtering operation) will be achieved using the candidate material to be deposited.

The controller 236 (or another system) may be configured to train, update, and/or refine the machine learning model to increase the accuracy of the outcomes and/or parameters determined using the machine learning model. The controller 236 may train, update, and/or refine the machine learning model based on feedback and/or results from the subsequent deposition operation, as well as from historical or related deposition operations (e.g., from hundreds, thousands, or more historical or related deposition operations) performed by the deposition tool 200.

The number and arrangement of devices shown in FIG. 2 are provided as one or more examples. In practice, there may be additional devices, fewer devices, different devices, or differently arranged devices than those shown in FIG. 2. Furthermore, two or more devices shown in FIG. 2 may be implemented within a single device, or a single device shown in FIG. 2 may be implemented as multiple, distributed devices.

FIGS. 3A and 3B are diagrams 300 related to an example chamber of a deposition tool described herein (e.g., the processing chamber 202 of the deposition tool 200). In some implementations, the dielectric coating 234 is applied to the sidewalls of the processing chamber 202 using a deposition process such as an electroplating process or another suitable deposition process.

FIG. 3A shows the processing chambers 202a and 202b. Sidewalls of the processing chamber 202a exclude the dielectric coating 234. In the processing chamber 202a, the plasma 210a is formed in the processing during a deposition operation (e.g., a sputtering operation) that deposits material from the target structure 208 to the semiconductor substrate 206.

FIG. 3A further shows processing chamber 202b. In contrast to the processing chamber 202a, sidewalls of the processing chamber 202b include the dielectric coating 234. The plasma 210b is formed in the processing chamber 202b during a deposition operation (e.g., a sputtering operation) that deposits material from the target structure 208 to the semiconductor substrate 206. As an example, the target structure 208 may include an aluminum (Al) material. The deposition operation may generate positively-charged ions 302 (e.g., Al³⁺ cations).

During the deposition operation in the processing chamber 202b, the dielectric coating 234 may promote and/or increase a likelihood of an accumulation of a negative charge (e.g., electrons 304) near sidewalls of the processing chamber 202b. In some implementations, the likelihood of the accumulation of the negative charge is based on one or more electrical performance properties of the dielectric coating 234 (e.g., a dielectric strength and/or an impedance of the dielectric coating 234). The positively-charged ions 302 may be drawn to the negative charge (e.g., the electrons 304) near the dielectric coating 234. As described in greater detail in connection with FIG. 3B, the drawing of the positively-charged ions 302 to the negative charge may improve a uniformity of an electromagnetic field within the processing chamber 202. Using the electromagnetic field, and as shown in FIG. 3A, a distribution of the plasma 210b (e.g., over the substrate 206) may be improved relative to a distribution of the plasma 210a.

FIG. 3B shows examples of the processing chamber 202a and the processing chamber 202b, where the processing chamber 202a excludes the dielectric coating 234 and the processing chamber 202b includes the dielectric coating 234. Additionally, the processing chamber 202a includes the electromagnetic field 306a and the processing chamber 202b includes the electromagnetic field 306b. The electromagnetic field 306a and/or the electromagnetic field 306b may be generated by one or more power circuits configured to generate the electromagnetic field 306 within the processing chamber 202 (the radio frequency power circuit 212 and/or the direct current power circuit 214, among other examples).

As shown in FIG. 3B, a strength 308 of the electromagnetic field 306a and/or 306b (e.g., a strength in volts per meter (V/m)) is based on a lateral position 310 and a vertical position 312 within the processing chambers 202a and/or 202b. The electromagnetic fields 306a and 306b include respective variances in strength 314a and 314b.

As an example, and based on the lateral position 310 and the vertical position within the processing chamber 202a (e.g., excluding the dielectric coating 234), the variance in strength 314a may be approximately 6×10¹¹ V/m. In contrast, and based on the lateral position 310 and the vertical position within the processing chamber 202b (e.g., including the dielectric coating 234), the variance in strength 314b may be approximately 4×10¹¹ V/m.

The difference between the variation in strength 314a and the variation in strength 314b of (e.g., a difference of approximately 50%) results from an accumulation of a negative charge near the sidewalls of the processing chamber 202b (e.g., an accumulation of the electrons 304 near the sidewalls of the processing chamber 202). Furthermore, the reduction in the variation of the strength 308 improves a uniformity of the electromagnetic field 306b relative to the uniformity of the electromagnetic field 306a. The improved uniformity of the electromagnetic field 306b, in turn, improves a uniformity of a material being deposited onto a semiconductor substrate (e.g., the semiconductor substrate 206) within the processing chamber 202b during a deposition operation relative to a uniformity of another material being deposited onto another semiconductor substrate within the processing chamber 202a.

As indicated above, FIGS. 3A and 3B are provided as an example. Other examples may differ from what is described with regard FIGS. 3A and 3B.

As described in connection with FIGS. 2, 3A, and 3B, a deposition tool (e.g., the deposition tool 200) includes a chamber (e.g., the processing chamber 202). The deposition tool includes a pedestal component (e.g., the pedestal component 204) within the chamber. The deposition tool includes a dielectric coating (e.g., the dielectric coating 234) on sidewalls of the chamber that are adjacent to the pedestal component, where the dielectric coating is configured to improve a uniformity of an electromagnetic field (e.g., the electromagnetic field 306) generated within the chamber during a plasma-based deposition operation that deposits particles of a target material (e.g., particles of a material from the target structure 208) onto a semiconductor substrate (e.g., the semiconductor substrate 206) held by the pedestal component.

Additionally, or alternatively, a deposition tool (e.g., the deposition tool 200) includes a chamber (e.g., the processing chamber 202). The deposition tool includes a pedestal component (e.g., the pedestal component 204) adjacent to a sidewall of the chamber. The deposition tool includes a dielectric coating (e.g., the dielectric coating 234) on the sidewall, where the dielectric coating promotes an accumulation of a negative charge (e.g., an accumulation of the electrons 304) near the sidewall during a sputtering operation within the chamber.

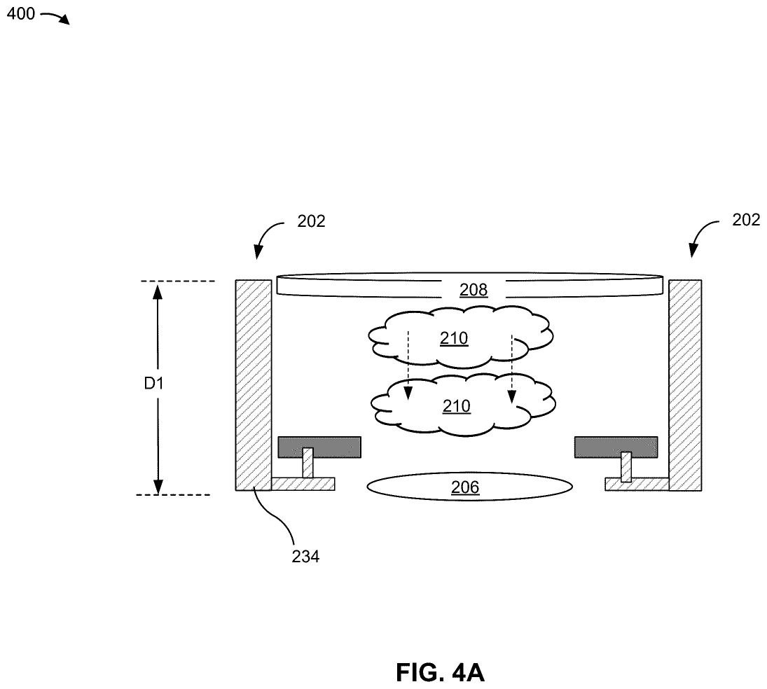

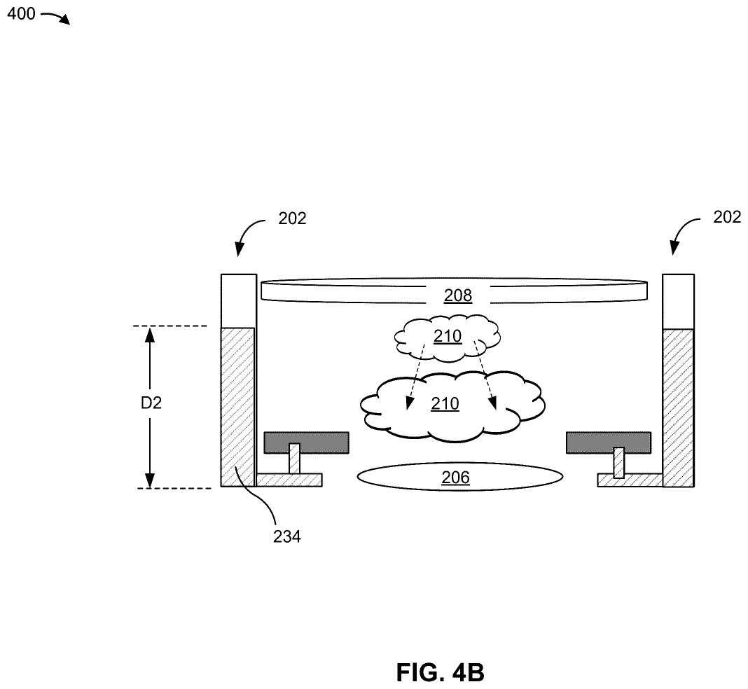

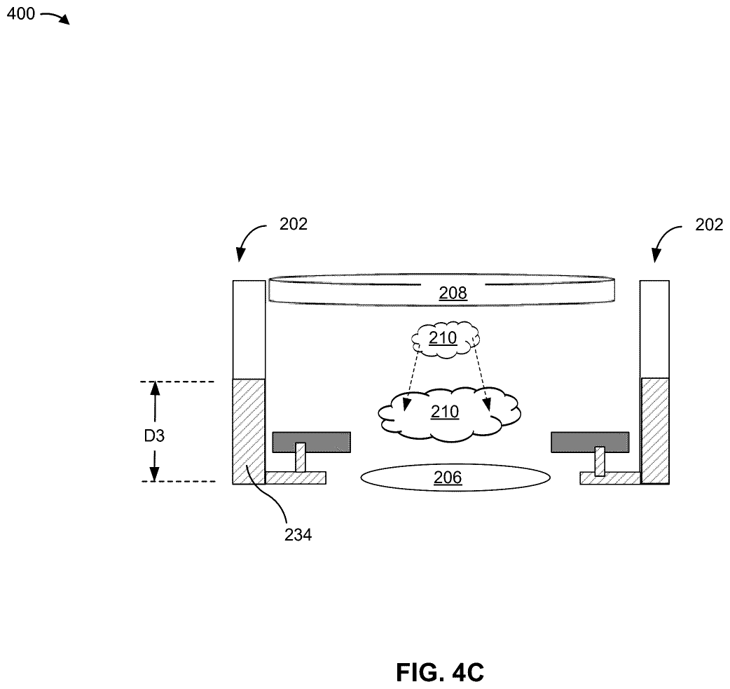

FIG. 4A-4C are diagrams 400 of example implementations described herein. The example implementations include different coverage heights for the dielectric coating 234 on sidewalls of the processing chamber 202 (e.g., different sidewall coverage heights).

As shown in the example of FIG. 4A, a sidewall coverage height of the dielectric coating 234 extends above the semiconductor substrate 206 (e.g., above the pedestal component 204) a distance D1. The distance D1 may correspond to an entire sidewall coverage height (e.g., approximately 100 millimeters) of the sidewall. A sidewall coverage height corresponding to the distance D1 may be selected to attain a first desired degree of uniformity of an electromagnetic field (e.g., the electromagnetic field 306) within the processing chamber 202. For example, selecting the sidewall coverage height corresponding to the distance D1 enables an accumulation of electrons (e.g., the electrons 304) along an entirety of the sidewall to lessen a variance in a strength of an electromagnetic field (e.g., the electromagnetic field 306) near and/or along the entirety of the sidewall.

As shown in the example of FIG. 4B, a sidewall coverage height of the dielectric coating 234 extends above the semiconductor substrate 206 (e.g., above the pedestal component 204) a distance D2. The distance D2, which is lesser relative to the distance D1 of FIG. 4A, may correspond to a partial sidewall coverage height (e.g., approximately 70 millimeters) of the sidewall. A sidewall coverage height corresponding to the distance D2 may be selected to attain a second desired degree of uniformity of an electromagnetic field (e.g., the electromagnetic field 306) within the processing chamber 202. For example, selecting the sidewall coverage height corresponding to the distance D2 promotes an accumulation of electrons (e.g., the electrons 304) along a portion of the sidewall (e.g., along a portion or region of the sidewall having a length of approximately 70 millimeters) to lessen a variance in a strength of an electromagnetic field (e.g., the electromagnetic field 306) near and/or along the portion of the sidewall, and maintain a pre-existing variance in the strength of the electromagnetic field that is not along the portion.

As shown in the example of FIG. 4C, a sidewall coverage height of the dielectric coating 234 extends above the semiconductor substrate 206 (e.g., above the pedestal component 204) a distance D3. The distance D3, which is lesser relative to the distance D2 of FIG. 4B, may correspond to a partial sidewall coverage height (e.g., approximately 30 millimeters) of the sidewall. A sidewall coverage height corresponding to the distance D3 may be selected to attain a third desired degree of uniformity of an electromagnetic field (e.g., the electromagnetic field 306) within the processing chamber 202. For example, selecting the sidewall coverage height corresponding to the distance D3 promotes an accumulation of electrons (e.g., the electrons 304) along a portion of the sidewall (e.g., along a portion or region of the sidewall having a length of approximately 30 millimeters) to lessen a variance in a strength of an electromagnetic field (e.g., the electromagnetic field 306) near and/or along the portion of the sidewall, and maintain a pre-existing variance in the strength of the electromagnetic field that is not along the portion.

In FIGS. 4A-4C, and with variations in sidewall coverage heights of the dielectric coating 234 (e.g., the distances D1-D3), the plasma 210 flowing through the processing chamber 202 (e.g., including particulates being from the target structure being deposited onto the semiconductor substrate) may be influenced by the electromagnetic field for different durations of time. For example, and for an entire sidewall coverage height (e.g., the distance D1 of FIG. 4A), a duration of the influence may be greater relative to a duration associated with a partial sidewall coverage height (e.g., the distance D2 of FIG. 4B and/or the distance D3 of FIG. 4C). With the greater duration, a uniformity may be increased.

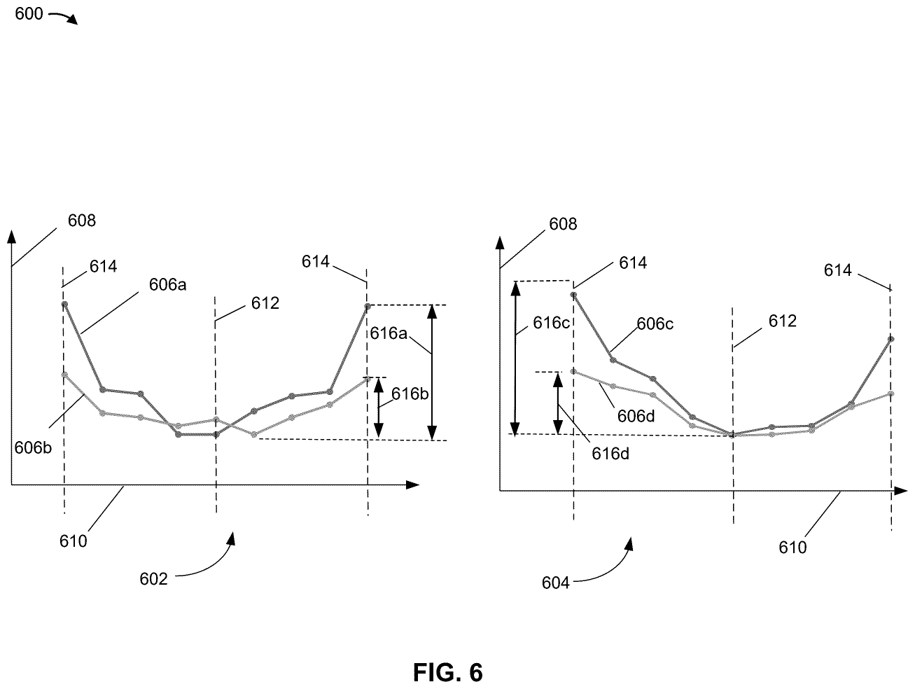

As described in greater detail in connection with FIG. 6, a mismatch profile of a material being deposited by a deposition tool (e.g., the deposition tool 200) may vary based on the distance D1, D2, and/or D3. In some implementations, and as described in greater detail in connection with FIG. 6, a mismatch profile associated with the distance D2 may be lesser relative to a mismatch profile associated with the distance D3. Additionally, or alternatively, a mismatch profile associated with the distance D1 may be lesser relative to a mismatch profile associated with the distance D2.

In each of the examples of FIGS. 4A-4C, a thickness of the dielectric coating 234 may be included in a range of approximately 80 microns (μm) to approximately 100 μm. Selecting the thickness of at least approximately 80 μm increases a robustness of the dielectric coating 234 to withstand electromagnetic fields within the processing chamber 202 during a deposition operation; selecting a smaller thickness may result in damage to the dielectric coating 234 during the deposition operation. Selecting a thickness of no more than approximately 100 μm allows for sufficient robustness during the deposition operation; a larger thickness may unnecessarily increase a cost of the dielectric coating 234 and/or the deposition tool 200. However, other values and ranges for the thickness are within the scope of the present disclosure.

Further, and in each of the examples of FIGS. 4A-4C, a surface roughness (Ra) of the dielectric coating 234 may be included in a range of approximately 10 μm to approximately 14 μm. Selecting a surface roughness of at least approximately 10 μm may increase an adhesion of the dielectric coating 234 on the sidewalls of the processing chamber 202 and/or reduce a particle count within the processing chamber 202 during a deposition operation; selecting a lesser surface roughness may result in the dielectric coating 234 peeling from the sidewalls and/or increase contamination within the processing chamber 202 during the deposition operation. Selecting a surface roughness of no more than approximately 14 μm allows for sufficient adhesion and/or reduced particle count during the deposition operation; a larger surface roughness may increase a likelihood of electrical arcing within the processing chamber 202 during the deposition operation. However, other values and ranges for the surface roughness are within the scope of the present disclosure.

As indicated above, FIGS. 4A-4C are provided as examples. Other examples may differ from what is described with regard FIGS. 4A-4C.

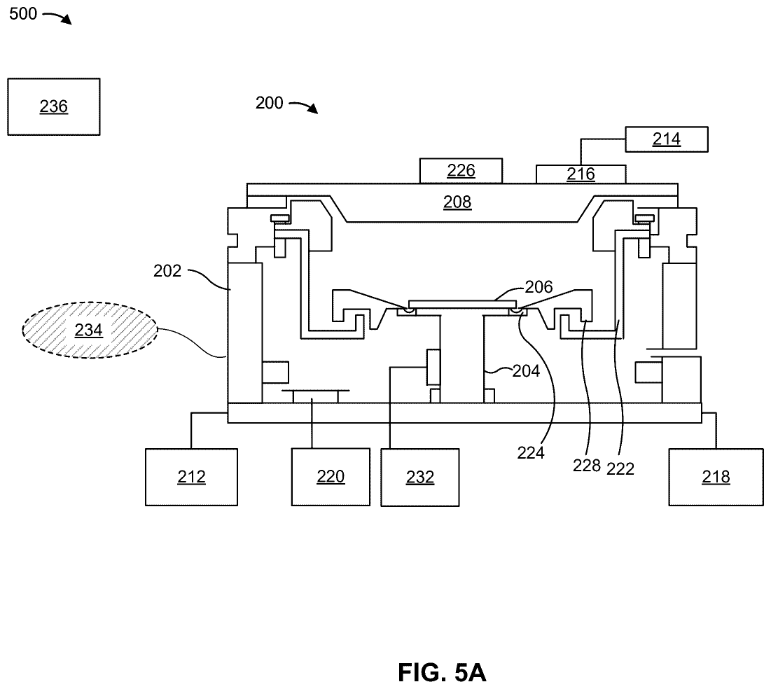

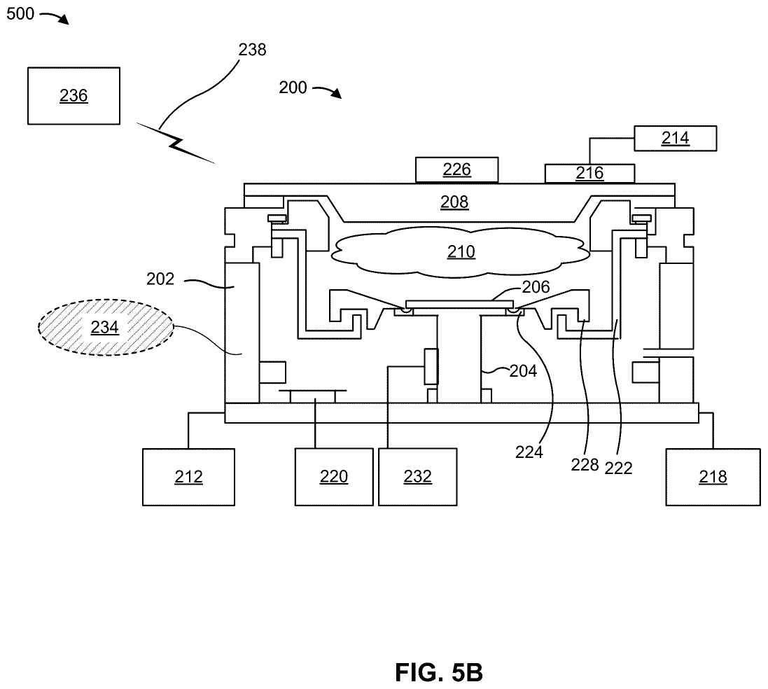

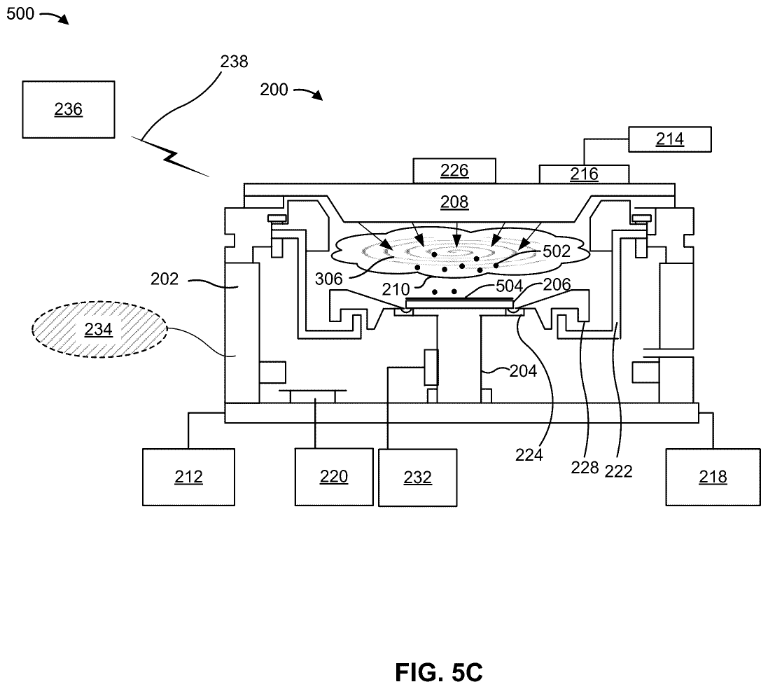

FIGS. 5A-5C are diagrams of an example implementation 500 described herein. In particular, the example implementation 500 includes an example process for performing a deposition operation using the deposition tool 200 described in connection with FIG. 2, FIG. 3A, FIG. 3B, FIGS. 4A-4C, and elsewhere herein. In some implementations, the deposition operation 4C corresponds to a sputtering deposition operation.

As shown in FIG. 5A, the deposition tool 200 receives the semiconductor substrate 206 onto the pedestal component 204 (e.g., the pedestal component 204 that is adjacent to a sidewall of the processing chamber 202 including the dielectric coating 234). The semiconductor substrate 206 is received below the target structure 208. In some implementations, the deposition tool 200 receives the semiconductor substrate 206 using the semiconductor substrate transfer system 126 as described in connection with FIG. 1.

As shown in FIG. 5B, and as part of activating the plasma 210, the controller 236 uses the communication link 238 to transmit a signal to the gas supply system 218 and initiate a flow of a gas (e.g., a krypton (Kr) gas, among other examples) into the processing chamber 202. The controller 236 may further transmit a signal using the communication link 238 to activate the radio frequency power circuit 212. Initiating the flow of the gas and activating the radio frequency power circuit 212 may generate the plasma 210 within the processing chamber 202.

As shown in FIG. 5C, a sputtering deposition operation occurs within the processing chamber 202. Particulates 502 from the target structure 208 are dislodged and accelerated towards the semiconductor substrate 206 to form a layer of a material 504 on a surface of the semiconductor substrate 206.

As part of the sputtering operation, the electromagnetic field 306 develops in the processing chamber 202. As described in connection with FIG. 2, FIG. 3A, FIG. 3B, FIGS. 4A-4C, and elsewhere herein, negative charges near the dielectric coating 234 may improve a uniformity of the electromagnetic field 306. Improving the uniformity of the electromagnetic field 306 may, in turn, reduce a center-to-edge mismatch of the layer of the material 504 on the semiconductor substrate 206.

In some implementations, the controller 236 transmits additional signaling to the radio frequency power circuit 212 and/or the direct current power circuit 214 to modulate the electromagnetic field 306 within the processing chamber 202. Additionally, or alternatively and in some implementations, the controller 236 transmits additional signaling to the pedestal component positioning system 232 to adjust a setting that controls a vertical position of the pedestal component 204 and/or the semiconductor substrate 206. As described in connection with FIG. 2, the controller 236 may use a machine learning model to determine an adjustment to the setting.

As described in connection with FIGS. 5A-5C, a deposition tool (e.g., the deposition tool 200) may perform a series of operations. The series of operations includes receiving, in a chamber (e.g., the processing chamber 202) of the deposition tool, a semiconductor substrate (e.g., the semiconductor substrate 206). The series of operations includes performing, using the deposition tool, a deposition operation that includes forming a layer of a material (e.g., the layer of the material 504) on the semiconductor substrate, where performing the deposition operation includes performing a plasma-based deposition operation using an electromagnetic field (e.g., the electromagnetic field 306) within the chamber, and where a dielectric coating (e.g., the dielectric coating 234) on sidewalls of the chamber increases a uniformity of the electromagnetic field within the chamber to reduce a center-to-edge mismatch of the layer of the material on the semiconductor substrate.

As indicated above, FIGS. 5A-5C are provided as an example. Other examples may differ from what is described with regard to FIGS. 5A-5C.

FIG. 6 includes diagrams of example data 600 related to deposition of a material using the deposition tool 200 described herein. As shown in FIG. 6, example 602 and example 604 include profile(s) 606 of layers of materials (e.g., different instances of the layer of the material 504) being deposited onto a semiconductor substrate (e.g., the semiconductor substrate 206). Each profile includes height(s) 608 of a layer of a material (e.g., the layer of the material 504) relative to lateral positions 610 of the material on the semiconductor substrate (e.g., a lateral zone of the semiconductor substrate 206). The lateral positions 610 includes a center position 612 and an edge position 614.

Example 602 includes the profile 606a relative to the profile 606b. The profile 606a may correspond to a profile of a layer of a material deposited by the deposition tool 200, where the deposition tool 200 excludes a dielectric coating on sidewalls of a chamber (e.g., excludes the dielectric coating 234 on sidewalls of the processing chamber 202). In contrast, the profile 616b may correspond to a profile of a layer of the material deposited by the deposition tool 200, where the deposition tool 200 includes a dielectric coating (e.g., the dielectric coating 234 including an aluminum oxide material) that extends above a pedestal component (e.g., the pedestal component 204) an entire sidewall coverage height (e.g., the sidewall coverage height D1 as described in connection with FIG. 4A).

As examples, heights related to the profile 606a may be included in a range 616a from approximately 0.5 μm to approximately 6.5 μm. In contrast, heights related to the profile 606b may be included in the range 616b from approximately 0.5 μm to approximately 3.5 μm. The range 616b of the profile 606b (e.g., a difference between the center position 610 and the edge position 612, also referred to as a center-to-edge mismatch) is lesser relative to the range 616a of the profile 606a.

Example 604 includes the profile 606c relative to the profile 616d. The profile 606c may correspond to a profile of a layer of the material deposited by the deposition tool 200, where the deposition tool 200 includes a dielectric coating (e.g., the dielectric coating 234 including an aluminum oxide material) that extends above a pedestal component (e.g., the pedestal component 204) a first sidewall coverage height (e.g., the sidewall coverage height D3 as described in connection with FIG. 4C). In contrast, the profile 606d may correspond to a profile of a layer of the material deposited by the deposition tool 200, where the deposition tool 200 includes a dielectric coating (e.g., the dielectric coating 234 including an aluminum oxide material) that extends above a pedestal component (e.g., the pedestal component 204) a second sidewall coverage height (e.g., the sidewall coverage height D2 as described in connection with FIG. 4B), where the second sidewall coverage height is greater relative to the first sidewall coverage height.

As examples, heights related to the profile 606c may be included in the range 616c from approximately 1.0 μm to approximately 13.0 μm. In contrast, heights related to the profile 606d may be included in the range 616d from approximately 1.0 μm to approximately 6.0 μm. The range 616d of the profile 606d (e.g., a difference between the center position 610 and the edge position 612, also referred to as a center-to-edge mismatch) is lesser relative to the range 616c of the profile 606c.

As indicated above, FIG. 6 is provided as an example. Other examples may differ from what is described with regard to FIG. 6, and include other profiles, heights, and/or ranges that are within the scope of the present disclosure.

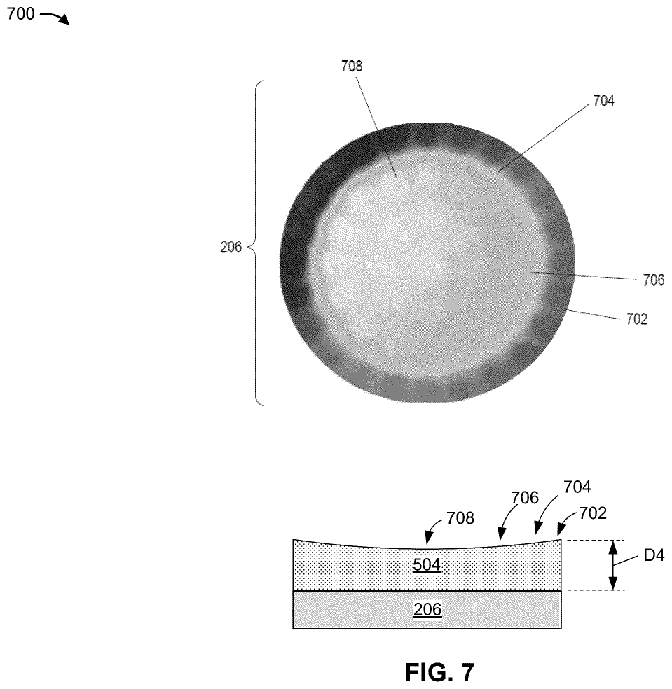

FIG. 7 includes a diagram of example data 700 related to deposition of a material using the deposition tool 200 described herein. As shown in FIG. 7, a top-view map of the semiconductor substrate 206 includes regions 702-708. Each of the regions 702-708 corresponds to a ring-shaped region that indicates a height of a material on the semiconductor substrate 206. As shown in a corresponding side-view, the regions 702-708 may include a height D4 (e.g., a range of heights) for a layer of a material (e.g., the layer of the material 504) deposited by the deposition tool 200 on a semiconductor substrate (e.g., the semiconductor substrate 206), where the deposition tool 200 includes a dielectric coating (e.g., the dielectric coating 234 including an aluminum oxide material) that extends above a pedestal component (e.g., the pedestal component 204) an entire sidewall coverage height (e.g., the sidewall coverage height D1 as described in connection with FIG. 4A).

As shown in FIG. 7, heights of the region 702 may be included in a range of approximately 420 angstroms (Å) to approximately 450 Å. Additionally, or alternatively, heights of region 704 may be included in a range of approximately 450 Å to approximately 470 Å. Additionally, or alternatively, heights of the region 706 may be included in a range of approximately 470 Å to approximately 485 Å. Additionally, or alternatively, heights of the region 708 may be included in a range of approximately 485 Å to approximately 495 Å.

As indicated above, FIG. 7 is provided as an example. Other examples may differ from what is described with regard to FIG. 7, and include other regions, heights, and/or ranges that are within the scope of the present disclosure.

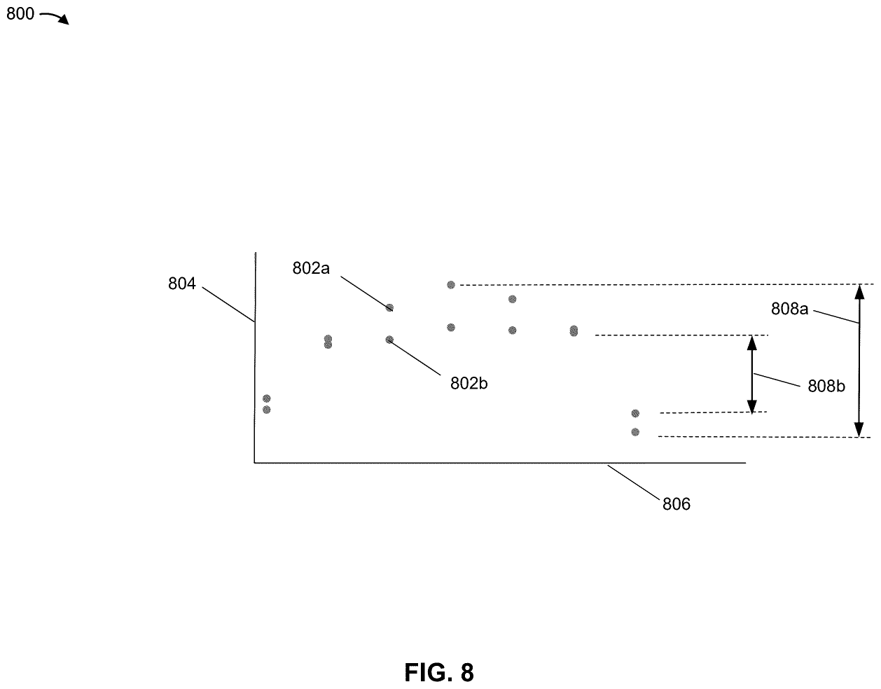

FIG. 8 includes diagrams of example data 800 related to deposition of a material using the deposition tool 200 described herein. As shown in FIG. 8, data 802 may correspond a layer of a material (e.g., different instances of the layer of the material 504) being deposited onto a semiconductor substrate (e.g., the semiconductor substrate 206). Each data point of the data 802 includes a thickness 804 of the layer of material (e.g., the layer of the material 504) relative to lateral positions 806 of the material on the semiconductor substrate (e.g., a lateral zone of the semiconductor substrate 206).

Data 802a corresponds to the layer of the material being deposited by the deposition tool 200, where the deposition tool 200 excludes a dielectric coating on sidewalls of a chamber (e.g., excludes the dielectric coating 234 on sidewalls of the processing chamber 202). As an example, and for the data 802a and as shown in FIG. 8, the thickness 802 may be included in a range 808a of approximately 420 Å to approximately 520 Å.

In contrast, data 802b corresponds to the layer of the material being deposited by the deposition tool 200, where the deposition tool 200 includes a dielectric coating (e.g., the dielectric coating 234 on the sidewalls of the processing chamber 202, where the dielectric coating 234 includes an aluminum oxide material). In some implementations, the dielectric coating extends above a pedestal component an entire sidewall coverage height (e.g., extends the sidewall coverage height D1 as described in connection with FIG. 4A). As an example, and for the data 808b and as shown in FIG. 8, the thickness 802 may be included in a range 808b of approximately 440 Å to approximately 480 Å.

As indicated above, FIG. 8 is provided as an example. Other examples may differ from what is described with regard to FIG. 8 and include other thicknesses and/or ranges that are within the scope of the present disclosure.

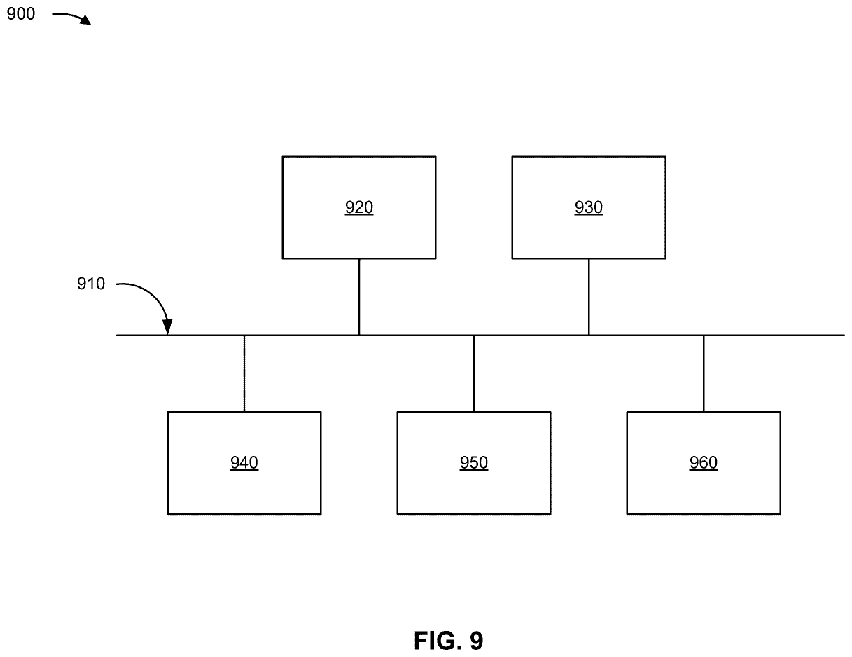

FIG. 9 is a diagram of example components of a device 900 associated with a deposition tool described herein (e.g., the deposition tool 200). The device 900 may correspond to one or more devices within the deposition tool 200 (e.g., the controller 236, the pedestal component positioning system 232, the radio frequency power circuit 212, the direct current power circuit 214, the gas supply system 218, and/or the pedestal component positioning system 232). In some implementations, the deposition tool 200 may include one or more devices 900 and/or one or more components of the device 900. As shown in FIG. 9, the device 900 may include a bus 910, a processor 920, a memory 930, an input component 940, an output component 950, and/or a communication component 960.

The bus 910 may include one or more components that enable wired and/or wireless communication among the components of the device 900. The bus 910 may couple together two or more components of FIG. 9, such as via operative coupling, communicative coupling, electronic coupling, and/or electric coupling. For example, the bus 910 may include an electrical connection (e.g., a wire, a trace, and/or a lead) and/or a wireless bus. The processor 920 may include a central processing unit, a graphics processing unit, a microprocessor, a controller, a microcontroller, a digital signal processor, a field-programmable gate array, an application-specific integrated circuit, and/or another type of processing component. The processor 920 may be implemented in hardware, firmware, or a combination of hardware and software. In some implementations, the processor 920 may include one or more processors capable of being programmed to perform one or more operations or processes described elsewhere herein.

The memory 930 may include volatile and/or nonvolatile memory. For example, the memory 930 may include random access memory (RAM), read only memory (ROM), a hard disk drive, and/or another type of memory (e.g., a flash memory, a magnetic memory, and/or an optical memory). The memory 930 may include internal memory (e.g., RAM, ROM, or a hard disk drive) and/or removable memory (e.g., removable via a universal serial bus connection). The memory 930 may be a non-transitory computer-readable medium. The memory 930 may store information, one or more instructions, and/or software (e.g., one or more software applications) related to the operation of the device 900. In some implementations, the memory 930 may include one or more memories that are coupled (e.g., communicatively coupled) to one or more processors (e.g., processor 920), such as via the bus 910. Communicative coupling between a processor 920 and a memory 930 may enable the processor 920 to read and/or process information stored in the memory 930 and/or to store information in the memory 930.

The input component 940 may enable the device 900 to receive input, such as user input and/or sensed input. For example, the input component 940 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 950 may enable the device 900 to provide output, such as via a display, a speaker, and/or a light-emitting diode. The communication component 960 may enable the device 900 to communicate with other devices via a wired connection and/or a wireless connection. For example, the communication component 960 may include a receiver, a transmitter, a transceiver, a modem, a network interface card, and/or an antenna.

The device 900 may perform one or more operations or processes described herein. For example, a non-transitory computer-readable medium (e.g., memory 930) may store a set of instructions (e.g., one or more instructions or code) for execution by the processor 920. The processor 920 may execute the set of instructions to perform one or more operations or processes described herein. In some implementations, execution of the set of instructions, by one or more processors 920, causes the one or more processors 920 and/or the device 900 to perform one or more operations or processes described herein. In some implementations, hardwired circuitry may be used instead of or in combination with the instructions to perform one or more operations or processes described herein. Additionally, or alternatively, the processor 920 may be configured to perform one or more operations or processes described herein. Thus, implementations described herein are not limited to any specific combination of hardware circuitry and software.

The number and arrangement of components shown in FIG. 9 are provided as an example. The device 900 may include additional components, fewer components, different components, or differently arranged components than those shown in FIG. 9. Additionally, or alternatively, a set of components (e.g., one or more components) of the device 900 may perform one or more functions described as being performed by another set of components of the device 900.

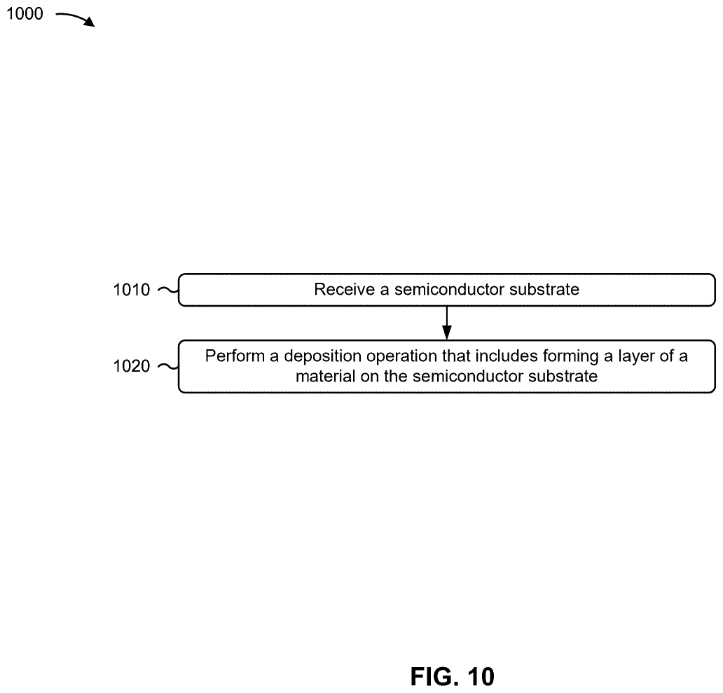

FIG. 10 is a flowchart of an example process 1000 associated with the deposition tool 200 of FIG. 2. In some implementations, one or more process blocks of FIG. 10 are performed using the deposition tool 200. In some implementations, one or more process blocks of FIG. 10 are performed using another device or a group of devices separate from or including the deposition tool 200, such as the semiconductor processing tool 100 and/or the controller 236. Additionally, or alternatively, one or more process blocks of FIG. 10 may be performed by one or more components of device 900, such as processor 920, memory 930, input component 940, output component 950, and/or communication component 960.

As shown in FIG. 10, process 1000 may include receiving, in a chamber of a deposition tool, a semiconductor substrate (block 1010). For example, a deposition tool (e.g., the deposition tool 200) may be used to receive, in a chamber of the deposition tool (e.g., the processing chamber 202), a semiconductor substrate (e.g., the semiconductor substrate 206), as described above.

As further shown in FIG. 10, process 1000 may include performing, using the deposition tool, a deposition operation that includes forming a layer of a material on the semiconductor substrate (block 1020). For example, the deposition tool may be used to perform a deposition operation that includes forming a layer of a material (e.g., the layer of material 504) on the semiconductor substrate. In some implementations, performing the deposition operation includes performing a plasma-based deposition operation using an electromagnetic field (e.g., the electromagnetic field 306) within the chamber. In some implementations, a dielectric coating (e.g., the dielectric coating 234) on sidewalls of the chamber increases a uniformity of the electromagnetic field within the chamber to reduce a center-to-edge mismatch profile of the layer of the material on the semiconductor substrate, as described above.

Process 1000 may include additional implementations, such as any single implementation or any combination of implementations described below and/or in connection with one or more other processes described elsewhere herein.

In a first implementation, performing the plasma-based deposition operation using the electromagnetic field includes generating positively-charged ions (e.g., the positively-charged ions 302), where the positively-charged ions are drawn to electrons (e.g., the electrons 304) near the dielectric coating.

In a second implementation, process 1000 includes adjusting a vertical position of a pedestal component (e.g., the pedestal component 204) holding the semiconductor substrate to adjust the uniformity of the electromagnetic field.

In a third implementation, forming the layer of the material on the semiconductor substrate includes forming a layer of a tantalum nitride material, forming a layer a lead zirconate titanate material, forming a layer a silicon nitride material, forming a layer a silicon dioxide material, forming a layer a tantalum pentoxide material, or forming a layer a cobalt iron boron material.

In a fourth implementation, forming the layer of the material on the semiconductor substrate includes forming a layer of a piezoelectric material that is used as part of a microphone structure.

In a fifth implementation, forming the layer of the piezoelectric material includes forming a layer of an aluminum nitride material, or forming a layer of an aluminum scandium material.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

Some implementations described herein provide a deposition tool and methods of operation. The deposition tool may be used in the fabrication of integrated circuit devices to deposit materials and/or layers on a semiconductor substrate. The deposition tool may include a chamber (e.g., a processing chamber) that is coated with a dielectric coating on sidewalls of the chamber. The dielectric coating on the sidewalls of the chamber within the deposition tool increases a likelihood of a negative charge accumulating near the sidewalls of the chamber. The increased likelihood of negative charge accumulation near the sidewalls of the chamber may improve a uniformity of an electromagnetic field within the deposition tool (e.g., during a deposition operation) relative to another deposition too not including such a dielectric coating. The improved uniformity of the electromagnetic field may enable an improved uniformity of a material being deposited by the deposition tool to be achieved.

In this way, the dielectric coating described herein on the sidewalls of the chamber of the deposition tool may enable an increased integrated circuit device yield to be achieved relative to another to integrated circuit device yield that is achievable by another deposition tool that does not include the dielectric coating. By increasing the yield, an amount of resources needed to support a market of the integrated circuit devices (e.g., raw materials, labor, semiconductor manufacturing tools, and/or computing resources) is reduced. Furthermore, the improved uniformity may enable an increased performance for devices (e.g., microphones and/or other devices) of integrated circuit devices processed by the deposition too.

As described in greater detail above, some implementations described herein provide a method. The method includes receiving, in a chamber of a deposition tool, a semiconductor substrate. The method includes performing, using the deposition tool, a deposition operation that includes forming a layer of a material on the semiconductor substrate, where performing the deposition operation includes performing a plasma-based deposition operation using an electromagnetic field within the chamber, and where a dielectric coating on sidewalls of the chamber increases a uniformity of the electromagnetic field within the chamber to reduce a center-to-edge mismatch of the layer of the material on the semiconductor substrate.

As described in greater detail above, some implementations described herein provide a deposition tool. The deposition tool includes a chamber. The deposition tool includes a pedestal component within the chamber. The deposition tool includes a dielectric coating on sidewalls of the chamber that are adjacent to the pedestal component, where the dielectric coating is configured to improve a uniformity of an electromagnetic field generated within the chamber during a plasma-based deposition operation that deposits particles of a target material onto a semiconductor substrate held by the pedestal component.

As described in greater detail above, some implementations described herein provide a deposition tool. The deposition tool includes a chamber. The deposition tool includes a pedestal component adjacent to a sidewall of the chamber. The deposition tool includes a dielectric coating on the sidewall, where the dielectric coating promotes an accumulation of a negative charge near the sidewall during a sputtering operation within the chamber.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

As used herein, the term “and/or,” when used in connection with a plurality of items, is intended to cover each of the plurality of items alone and any and all combinations of the plurality of items. For example, “A and/or B” covers “A and B,” “A and not B,” and “B and not A.”

When “a processor” or “one or more processors” (or another device or component, such as “a controller” or “one or more controllers”) is described or claimed (within a single claim or across multiple claims) as performing multiple operations or being configured to perform multiple operations, this language is intended to broadly cover a variety of processor architectures and environments. For example, unless explicitly claimed otherwise (e.g., via the use of “first processor” and “second processor” or other language that differentiates processors in the claims), this language is intended to cover a single processor performing or being configured to perform all of the operations, a group of processors collectively performing or being configured to perform all of the operations, a first processor performing or being configured to perform a first operation and a second processor performing or being configured to perform a second operation, or any combination of processors performing or being configured to perform the operations. For example, when a claim has the form “one or more processors configured to: perform X; perform Y; and perform Z,” that claim should be interpreted to mean “one or more processors configured to perform X; one or more (possibly different) processors configured to perform Y; and one or more (also possibly different) processors configured to perform Z.”

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
receiving, in a chamber of a deposition tool, a semiconductor substrate; and
performing, using the deposition tool, a deposition operation that includes forming a layer of a material on the semiconductor substrate,
wherein performing the deposition operation includes performing a plasma-based deposition operation using an electromagnetic field within the chamber, and
wherein a dielectric coating on sidewalls of the chamber increases a uniformity of the electromagnetic field within the chamber to reduce a center-to-edge mismatch profile of the layer of the material on the semiconductor substrate.

2. The method of claim 1, wherein performing the plasma-based deposition operation using the electromagnetic field comprises:
generating positively-charged ions,
wherein the positively-charged ions are drawn to electrons near the dielectric coating.

3. The method of claim 1, further comprising:
adjusting a vertical position of a pedestal component holding the semiconductor substrate to adjust the uniformity of the electromagnetic field.

4. The method of claim 1, wherein forming the layer of the material on the semiconductor substrate comprises:
forming a layer of a tantalum nitride material,
forming a layer a lead zirconate titanate material,
forming a layer a silicon nitride material,
forming a layer a silicon dioxide material,
forming a layer a tantalum pentoxide material, or
forming a layer a cobalt iron boron material.

5. The method of claim 1, wherein forming the layer of the material on the semiconductor substrate comprises:
forming a layer of a piezoelectric material that is used as part of a microphone structure.

6. The method of claim 5, wherein forming the layer of the piezoelectric material comprises:
forming a layer of an aluminum nitride material, or
forming a layer of an aluminum scandium material.

7. A deposition tool, comprising:
a chamber;
a pedestal component within the chamber; and
a dielectric coating on sidewalls of the chamber that are adjacent to the pedestal component,
wherein the dielectric coating is configured to improve a uniformity of an electromagnetic field generated within the chamber during a plasma-based deposition operation that deposits particles of a target material onto a semiconductor substrate held by the pedestal component.

8. The deposition tool of claim 7, wherein the dielectric coating comprises:
an aluminum oxide material,
an aluminum nitride material,
a silicon nitride material,
a tantalum nitride material,
a tantalum pentoxide material, or
a yttrium oxide material.

9. The deposition tool of claim 7, wherein the dielectric coating comprises:
a dielectric material having a dielectric strength that is greater than approximately 15 kilovolts per millimeter.

10. The deposition tool of claim 7, wherein the dielectric coating comprises:
a dielectric material having an impedance that is greater than approximately 300 ohms.

11. The deposition tool of claim 7, wherein a roughness of the dielectric coating is included in a range of approximately 10 microns to approximately 14 microns.

12. The deposition tool of claim 7, further comprising:
a pedestal component positioning system, and
a controller configured to adjust a setting that controls a vertical position of the pedestal component positioning system to adjust a uniformity of the electromagnetic field during the plasma-based deposition operation.

13. The deposition tool of claim 12, wherein the controller uses a machine learning model to determine an adjustment to the setting.

14. The deposition tool of claim 13, wherein the controller is configured to train and update the machine learning model based on one or more of:
a material included in the dielectric coating,
a sidewall coverage height of the dielectric coating, or
a material deposited by the plasma-based deposition operation.

15. A deposition tool, comprising:
a chamber;
a pedestal component adjacent to a sidewall of the chamber; and
a dielectric coating on the sidewall,
wherein the dielectric coating promotes an accumulation of a negative charge near the sidewall during a sputtering operation within the chamber.

16. The deposition tool of claim 15, wherein the deposition tool further comprises:
the dielectric coating on a bottom surface of the chamber.

17. The deposition tool of claim 15, wherein the dielectric coating extends above the pedestal component an entire sidewall coverage height of the sidewall.

18. The deposition tool of claim 15, wherein the dielectric coating extends above the pedestal component a partial sidewall coverage height of the sidewall.

19. The deposition tool of claim 15, further comprising:
one or more power circuits configured to generate an electromagnetic field within the chamber during the sputtering operation.

20. The deposition tool of claim 19, wherein a location of the accumulation of the negative charge causes the accumulation of the negative charge to improve a uniformity of the electromagnetic field and reduce a mismatch profile of a layer of a material deposited on a semiconductor substrate during the sputtering operation.
